(19) United States
(12) Patent Application Publication
(10) Pub. No.: US 2012/0247558 A1
(43) Pub. Date: Oct. 4, 2012

(54) TRANSMITTANCE ENHANCEMENT FILM AND SOLAR CELL MODULE COMPRISING THE SAME

(76) Inventors: TSUN-MIN HSU, Kaohsiung (TW); Yu-Ming Sun, Kaohsiung (TW); Chung-Hua Yang, Kaohsiung (TW); Yi-Chung Shih, Kaohsiung (TW); Jui-Kai Hu, Kaohsiung (TW)

(21) Appl. No.: 13/434,378

(22) Filed: Mar. 29, 2012

(30) Foreign Application Priority Data
Apr. 1, 2011 (TW) 100111944

(51) Int. Cl. H01L 31/0232; B32B 27/20; F21V 9/00; B32B 5/16

(52) U.S. Cl. 136/259; 428/426; 428/522; 428/447; 428/423.1; 252/582

(57) ABSTRACT

A transmittance enhancement film is provided, which includes a substrate and a coating layer on the substrate. The coating layer includes a plurality of organic particles and a binder. The organic particles have a refractive index of less than 1.5, and the refractive index ratio of the organic particles to the binder is in the range from 0.95 to 1.05. The transmittance enhancement film of the present invention is suitable for being used in a solar cell module, and is capable of enhancing the transmittance of light, thereby improving the power generation efficiency of the solar cell module.

### BACKGROUND OF THE INVENTION

1. Field of the Invention

The present invention relates to a transmittance enhancement film, particularly a transmittance enhancement film for use in a solar cell module.

2. Description of the Prior Art

Due to an increasingly concern of serious energy shortage and environmental protection issues such as greenhouse effect, many nations have been actively developing various alternative energy sources, among which solar power has attracted the most attention among the industries. As shown in FIG. 1, a solar cell module generally includes a transparent frontsheet 11 (commonly, a glass sheet), a solar cell unit 13 contained within an encapsulant layer 12, and a backsheet 14.

When sunlight in the atmosphere enters the solar cell module through the transparent frontsheet, photoelectric conversion occurs in the solar cell unit, so as to convert the light energy into electric energy to be outputted. However, the power generation efficiency of currently known solar cell module has been undesirable. For example, the power generation efficiency of the mostly widely used mono- or poly-crystalline silicon solar cell assembly is about 15%. In other words, only 15% of sunlight can be converted into useful electric energy, and the remaining 85% of sunlight is either wasted or converted into useless heat energy.

How to improve power generation efficiency of solar cell module is always one of the foci of research within the industries. Presently, one of the developed technologies is to track the optimal sunlight position by using an electronic tracking device, so as to adjust the angle of a light incident surface of a solar cell module to maintain the optimal light receiving efficiency. However, the electronic tracking device is a complex structure at a high cost, and requires regular maintenance, such that the total cost of a solar power module with such electronic tracking device would greatly increased. In addition, due to the use of the electronic tracking device, the overall mass of the solar cell module would substantially increase, making it inconvenient during installation.

A. W. Bett et al. discloses a solar cell module including several light concentrating units to increase the light concentration effect, and the main elements in each light concentrating unit are a Fresnel lens, a glass substrate with a heat sink, and a frame. However, since the elements are all made of glass, the totaled weight is substantial, making it inconvenient to be assembled.

In addition, another conventional technology is to process the glass frontsheet, by forming an embossed glass having a regular pattern, so as to improve light transmittance. However, this technology requires precise manufacturing technology and involves high cost, making it not an ideal technology to be adopted for mass production.

### SUMMARY OF THE INVENTION

In order to solve the above problems, the present invention is directed to a film which is convenient for preparation and assembly, and can improve the utilization of the solar light.

In order to achieve the above and other objectives, the present invention provides a transmittance enhancement film, which comprises a substrate and a coating layer on the substrate, wherein the coating layer comprises a plurality of organic particles and a binder, the organic particles have a refractive index of less than 1.5, and the refractive index ratio of the organic particles to the binder is in the range from 0.95 to 1.05.

The present invention further provides a solar cell module, characterized by containing the above-mentioned transmittance enhancement film.

### BRIEF DESCRIPTION OF THE DRAWINGS

The invention will be described according to the appended drawings in which:

FIG. 1 is a schematic view of a solar cell module in the prior art;

FIG. 2A is a schematic view illustrating the light loss of solar light entering the conventional solar cell module shown in FIG. 1 due to reflection;

FIG. 2B is a schematic view of an embodiment of a transmittance enhancement film used in a solar cell module according to the present invention;

FIGS. 3 to 6 are embodiments of a solar cell module according to the present invention;

FIGS. 7 to 10 are respectively schematic views of solar cell assemblies A, A1, and A3;

FIGS. 11 to 13 are respectively schematic views of solar cell assemblies B, C, and D;

FIGS. 14 and 15 are respectively schematic views of solar cell assemblies C1 and C2;

FIGS. 16 and 17 are respectively schematic views of solar cell assemblies D1 and D2;

FIGS. 18 and 19 respectively illustrate the influence of the coating thickness of transmittance enhancement films (having a B/R value from 0.4 to 1.0 and a B/R value from 1.6 to 2.0) on the power generation efficiency η while α=0.97 and n_{B}=1.43 are fixed; and

FIGS. 20 to 22 respectively illustrate the influence of α, n_{B}, and the coating thickness of transmittance enhancement films on the power generation efficiency η while B/R is fixed at 0.6, 1.0, or 1.6.

### DETAILED DESCRIPTION OF THE INVENTION

The substrate useful for the transmittance enhancement film of the present invention may be any transparent substrate known to persons of ordinary skill in the art, for example, glass or plastic. The plastic substrate is not particularly limited, and includes, for example, but is not limited to, polyester resin, such as, polyethylene terephthalate (PET) or polyethylene naphthalate (PEN); polymethacrylate resin, such as, polymethyl methacrylate (PMMA); polyimide resin; polystyrene resin; polycycloolefin resin; polyolefin resin; polycarbonate resin; polyurethane resin; triacetate cellulose (TAC); or a mixture thereof, with PET, PMMA, polycycloolefin resin, or a mixture thereof being preferred, and PET being more preferred. The thickness of the substrate is not particularly limited, and is generally in the range from about 5 μm to about 300 μm.

The total light transmittance, the diffuse light transmittance, and the parallel light transmittance (Pt) of an optical product may be expressed as Tt=Td+Pt. The transmittance enhancement film of the present invention has the characteristics of high total light transmittance and low parallel light transmittance. The transmittance enhancement film of the present invention has a total light transmittance of greater than 93% as measured according to the ASTM E903-96 standard method, and a parallel light transmittance of less than 40% as measured according to the JIS K7136 standard method, and preferably has a total light transmittance of greater than 95% as measured according to the ASTM E903-96 standard method, and a parallel light transmittance of less than 30% as measured according to the JIS K7136 standard method.

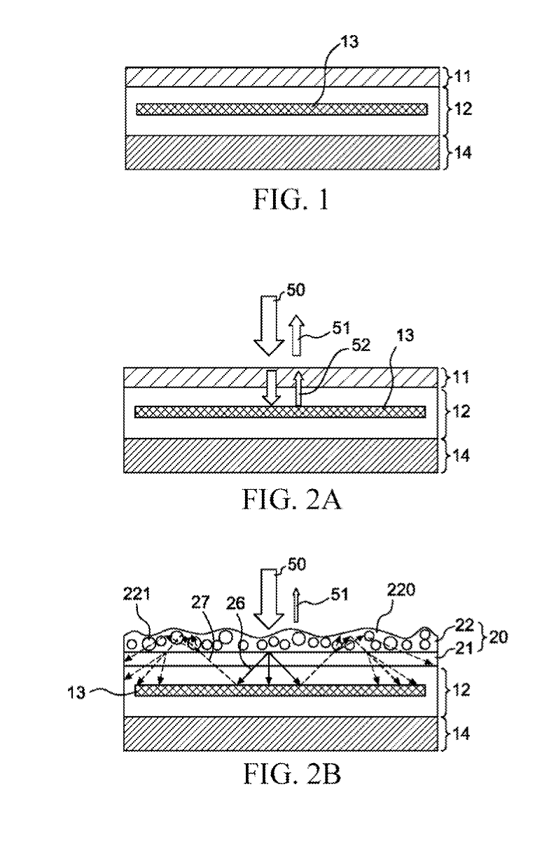

Generally, after the solar light enters the solar cell module, a part of the light is reflected and thus cannot effectively reach the solar cell unit, so that the power generation efficiency of the solar cell module is adversely influenced. FIG. 2A is a schematic view illustrating the light loss of solar light entering a conventional solar cell module as shown in FIG. 1 due to reflection. As shown in FIG. 2A, when the solar light 50 enters a solar cell module through a glass frontsheet 11, a first reflection 51 of part of the incident light occurs, and a second reflection 52 of another part of incident light entering an encapsulant layer 12 occurs. The reflected light reduces the utilization of the light ray incident on the solar cell module.

FIG. 2B is a schematic view of an embodiment of the transmittance enhancement film used in a solar cell module according to the present invention, in which the solar cell module includes a transparent frontsheet 11, a solar cell unit 13 contained in an encapsulant layer 12, and a backsheet 14 in sequence. A transmittance enhancement film 20 of the present invention includes a substrate 21 and a coating layer 22 on the substrate, wherein the coating layer contains a plurality of organic particles 220 and a binder 221.

As shown in FIG. 2B, when the solar light 50 enters the solar cell module via the transmittance enhancement film 20, compared with a conventional glass frontsheet, the transmittance enhancement film of the present invention can reduce the light loss resulting from the first reflection 51, thus improving the total light transmittance. In addition, when the solar light 50 enters the solar cell module via the transmittance enhancement film 20, light scattering occurs, when scattered light 26 contacts the cell unit 13, reflected light 27 is generated, and when the reflected light 27 enters the transmittance enhancement film 20, total reflection occurs, such that the light travels again in the direction towards the cell unit 13. Therefore, the transmittance enhancement film of the present invention has a high total light transmittance, and can redirect the reflected light, such that the reflected light travels along the light incident direction again, thereby improving the utilization of the solar light and the power generation efficiency of the solar cell module.

Generally, the increase in the total light transmittance caused by such a transmittance enhancement film is referred to as “gain” of the transmittance enhancement film. The gain of the transmittance enhancement film refers to a difference between “the total light transmittance tested after the film is disposed” to a sample to be tested (for example, a glass or plastic substrate) and “the total light transmittance tested before the film is disposed” to the sample to be tested. According to a preferred embodiment of the present invention, the “gain” of transmittance enhancement film of the present invention may be up to 2% or more of the total light transmittance. In other words, the transmittance enhancement film of the present invention can increase the total light transmittance of the sample to be tested by 2% or more.

The transmittance enhancement film of the present invention has convex-concave microstructures, which can be prepared integrally with the substrate by, for example, pad printing, hot embossing, transferring, injection, or biaxial stretching; or prepared by processing on a substrate by any conventional method, such as, coating, spraying, and atomizing. For example, a coating composition containing organic particles and a binder is coated on a surface of a substrate, to form a coating layer having a microstructure. The species of the substrate are as described above. The thickness of the coating layer is not particularly limited, and is generally in the range from about 1 micrometer (μm) to about 50 μm depending on the size of the microstructure. The coating layer can be applied onto the light incident surface, the light emitting surface, or both the light incident surface and the light emitting surface, and preferably coated on either the light incident surface or the light emitting surface of the transparent substrate.

According to an embodiment of the present invention, the coating composition containing the organic particles and the binder is coated on the substrate by a coating method, to prepare the transmittance enhancement film of the present invention. Suitable coating methods are known to persons of ordinary skill in the art, such as, knife coating, roller coating, micro gravure coating, flow coating, dip coating, spray coating, and curtain coating, or a combination thereof. A preferred coating method is roller coating.

The organic particles useful in the present invention are, for example, but not limited to, poly(meth)acrylate resin, polyurethane resin, silicone resin, or a mixture thereof, preferably poly(meth)acrylate resin or silicone resin, and more preferably silicone resin.

The binder useful in the present invention is, for example, but not limited to, (meth)acrylic resin, silicone resin, polyamide resin, epoxy resin, fluorocarbon resin, polyimide resin, polyurethane resin, alkyd resin, polyester resin, or a mixture thereof, and preferably fluorocarbon resin due to its good weather resistance.

The fluorocarbon resin useful in the present invention includes a copolymer of a fluoroolefin monomer and an alkyl vinyl ether monomer.

The above-mentioned fluoroolefin monomer is well known to persons of ordinary skill in the art, which can be, for example, but is not limited to, vinyl fluoride, vinylidene fluoride, trifluorochloroethylene, tetrafluoroethylene, hexafluoropropylene, or a mixture thereof, with trifluorochloroethylene being preferred.

The above-mentioned alkyl vinyl ether monomer is not particularly limited, and can be selected from the group consisting of a linear alkyl vinyl ether monomer, a branched alkyl vinyl ether monomer, a cyclic alkyl vinyl ether monomer, a hydroxyalkyl vinyl ether monomer, and a mixture thereof. Preferably, the alkyl in the alkyl vinyl ether is a C₂-C₁₁ alkyl.

According to the present invention, the shape of the organic particles is not particularly limited, and can be, for example, spherical, ellipsoidal, or irregular in shape, and preferably spherical. The mean particle size of the organic particles is not particularly limited, and is generally in the range from about 0.5 micron (nm) to about 30 μm, preferably from about 0.5 μm to about 15 μm. According to an embodiment of the present invention, the organic particles have a mean particle size in the range from about 0.5 μm to about 9.0 μm.

According to the present invention, the content (x) of the organic particles is about 40 to about 200 parts by weight based on 100 parts by weight of the solids content of the binder.

According to the present invention, a photo initiator or any additives well known to persons of ordinary skill in the art, including, for example, but not limited to, a leveling agent, a stabilizer, a curing agent, a wetting agent, a fluorescent brightener or a UV absorber, can be added to the coating composition.

The transmittance enhancement film of the present invention is prepared by applying a coating composition containing a plurality of organic particles and a binder onto a transparent substrate to form a resin coating layer. In order to achieve the effect on improving the total light transmittance, the organic particles used in the present invention must have a refractive index of less than 1.5, and the refractive index ratio of the organic particles to the binder is in the range from 0.95 to 1.05. If the refractive index ratio of the organic particles to the binder is less than 0.95 or greater than 1.05, or the refractive index of the organic particles is greater than 1.5, a large amount of reflected light will be generated when the light is incident on the coating layer, thereby reducing the transmittance of the light.

The thickness of the coating layer is as described hereinbefore. However, according to the present invention, the thickness of the coating layer may be selected after the coating composition is selected, so as to obtain a transmittance enhancement film that has a better total light transmittance. According to an embodiment of the present invention, when the content (x) of the organic particles is 40 parts by weight≦x<150 parts by weight based on 100 parts by weight of the solids content of the binder, the thickness (y) of the coating layer is preferably selected to be greater than 20 μm. In another preferred embodiment of the present invention, when the content (x) of the organic particles is 150 parts by weight≦x≦200 parts by weight based on 100 parts by weight of the solids content of the binder, the thickness (y) of the coating layer is preferably selected to be less than 7 μm.

The transmittance enhancement film of the present invention has an optical property of an increase in the total light transmittance by 2% or more, and is applicable in any module requiring an increase in the total light transmittance, such as, a glass curtain of a building or garden class, so as to improve the light utilization. According to an embodiment of the present invention, the module design of the solar cell module does not need to be changed, and the transmittance enhancement film of the present invention may be applied in a solar cell module by any manner known to persons of ordinary skill in the art, for example, by directly coating the coating composition onto an element (for example, a frontsheet or an encapsulant) of a solar cell module to form a transmittance enhancement film; or the transmittance enhancement film of the present invention may be directly may be directly laminated and attached onto the transparent frontsheet or the encapsulant layer. When entering the transmittance enhancement film, the light contacts the organic particles contained in the coating layer, and a light scattering phenomenon occurs, such that total reflection of the light occurs in the cell element, and the light travels in the direction towards the cell element again, and is absorbed and utilized by the cell element, thereby improving the power generation effect.

Hereinafter, an embodiment of the transmittance enhancement film of the present invention applied in a solar cell module is further described with reference to the accompanying drawings, which are not intended to limit the scope of the present invention. Any modifications and changes that can be easily made by persons of ordinary skill in the art shall fall within the scope of the disclosure of this specification.

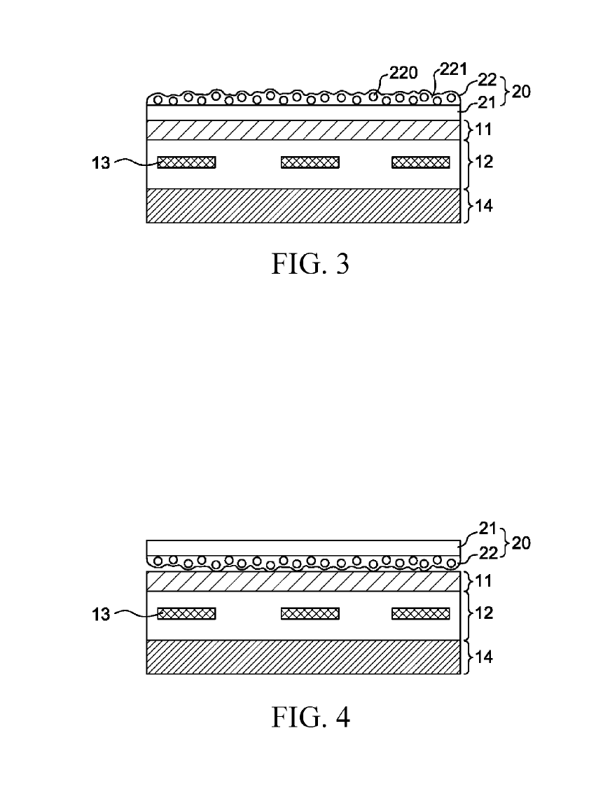

FIG. 3 shows an embodiment of a solar cell module according to the present invention. The solar cell module includes a transparent frontsheet 11, a solar cell unit 13 contained in an encapsulant layer 12, a backsheet 14, and a transmittance enhancement film 20 disposed on the transparent frontsheet 11. The transmittance enhancement film 20 includes a substrate 21 and a coating layer 22 on the substrate and the coating layer 22 is applied onto the light incident surface of the substrate 21, wherein the coating layer contains organic particles 220 and a binder 221.

FIG. 4 shows another embodiment of a solar cell module according to the present invention, wherein the transparent frontsheet 11, the encapsulant layer 12, the backsheet 14, and the transmittance enhancement film 20 are disposed in the same manner as shown in FIG. 3 except that the coating layer 22 is applied onto the light emitting surface of the substrate 21.

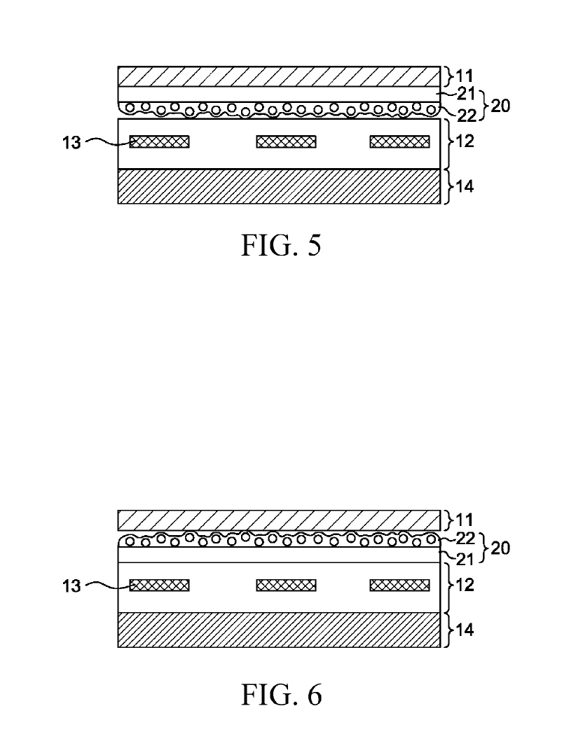

FIG. 5 shows a further implementation aspect of a solar cell module according to the present invention. The solar cell module includes a transparent frontsheet 11, a solar cell unit 13 contained in an encapsulant layer 12, a backsheet 14, and a transmittance enhancement film 20 disposed on the encapsulant layer 12 (i.e, deposed between the transparent frontsheet and the encapsulant layer). The transmittance enhancement film 20 includes a substrate 21 and a coating layer 22 on the substrate and the coating layer 22 is applied onto the light emitting surface of the substrate 21.

FIG. 6 shows a further embodiment of a solar cell module according to the present invention, wherein the transparent frontsheet 11, the encapsulant layer 12, the backsheet 14, and the transmittance enhancement film 20 are disposed in the same manner as shown in FIG. 5 except that the coating layer 22 is applied onto the light incident surface of the substrate 21.

According to another implementation aspect of the present invention, the transmittance enhancement film of the present invention can be used in the solar cell module in place of the transparent frontsheet. In this aspect, the coating layer can be located on the light incident surface or light emitting surface of the transmittance enhancement film.

The present invention further provides a solar cell module characterized by containing the transmittance enhancement film of the present invention.

In addition, the present invention provides a coating composition useful in the enhancement of light transmittance, which comprises a plurality of organic particles and a binder, wherein the organic particles have a refractive index of less than 1.5 and the refractive index ratio of the organic particles to the binder is in the range from 0.95 to 1.05. Preferably, the organic particles have a mean particle size in the range from 0.5 μm to 9.0 μm. The species and amounts of the organic particles and the binder are as described above.

The following examples are used to further illustrate the present invention, but not intended to limit the scope of the present invention. Any modifications or alterations that can be easily accomplished by persons skilled in the art fall within the scope of the disclosure of the specification and the appended claims.

### EXAMPLES

### Preparation of a Transmittance Enhancement Film for Use in a Solar Cell Module

### Comparative Example 1

A tempered glass plate having a thickness of 3.2 mm (Sunmax™, protective glass, Asahi Glass Co. Ltd.).

### Comparative Example 2

A polyethylene terephthalate (PET) film having a thickness of 250 μm (CH885, NAN YA Plastics Corporation).

### Comparative Example 3

29.56 grams of an epoxy acrylate resin (SUP-560, provided by Shin-A

Company, with a solids content of 100% and a refractive index of 1.57) were added into a plastic bottle, then 40 grams of a solvent (butyl acetate) and 29.56 grams of organic particles (Tospearl 145A, provided by Momentive Company, silicone resin solid spherical particles with a mean particle size of 4.5 μm and a refractive index of 1.43) were sequentially added under high speed stirring, and finally 0.88 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40, dried for 2 minutes at 120° C. and then irradiated with UV light (irradiation intensity: 500 mJ/cm²). Finally, a coating layer having a thickness of about 30 μm was obtained.

### Comparative Example 4

29.56 grams of an epoxy acrylate resin (SUP-560, provided by Shin-A Company, with a solids content of 100% and a refractive index of 1.57) were added into a plastic bottle, then 40 grams of a solvent (butyl acetate) and 29.56 grams of organic particles (SX-500H, provided by Soken Company, polystyrene resin solid spherical particles with a mean particle size of 5 μm and a refractive index of 1.59) were sequentially added under high speed stirring, and finally 0.88 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40, dried for 2 minutes at 120° C. and then irradiated with UV light (irradiation intensity: 500 mJ/cm²). Finally, a coating layer having a thickness of about 30 μm was obtained.

### Comparative Example 5

53.2 grams of an acrylate resin (ETERAC 7363-TS-50, provided by Eternal Chemical Co. Ltd., an acrylate copolymer resin with a solids content of 50% and a refractive index of 1.49) were added into a plastic bottle, then 11.13 grams of a solvent (butyl acetate) and 26.6 grams of organic particles (SX-500H, provided by Soken Company, polystyrene resin solid spherical particles with a mean particle size of 5 μm and a refractive index of 1.59) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40 and dried for 2 minutes at 120° C. Finally, a coating layer having a thickness of about 30 μm was obtained.

### Comparative Example 6

53.2 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 11.13 grams of a solvent (butyl acetate) and 26.6 grams of organic particles (SX-500H, provided by Soken Company, polystyrene resin solid spherical particles with a mean particle size of 5 μm and a refractive index of 1.59) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40 and dried for 2 minutes at 150° C. Finally, a coating layer having a thickness of about 30 μm was obtained.

### Example 1

29.56 grams of an epoxy acrylate resin (SUP-560, provided by Shin-A Company, with a solids content of 100% and a refractive index of 1.57) were added into a plastic bottle, then 40 grams of a solvent (butyl acetate) and 29.56 grams of organic particles (SSX-105, provided by Sekisui Company, polymethacrylate resin solid spherical particles with a mean particle size of 5 μm and a refractive index of 1.49) were sequentially added under high speed stirring, and finally 0.88 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40, dried for 2 minutes at 120° C. and then irradiated with UV light (irradiation intensity: 500 mJ/cm²). Finally, a coating layer having a thickness of about 30 μm was obtained.

### Example 2

53.2 grams of an acrylate resin (ETERAC 7363-TS-50, provided by Eternal Chemical Co. Ltd., an acrylate copolymer resin with a solids content of 50% and a refractive index of 1.49) were added into a plastic bottle, then 11.13 grams of a solvent (butyl acetate) and 26.6 grams of organic particles (Tospearl 145A, provided by Momentive Company, silicone resin solid spherical particles with a mean particle size of 4.5 μm and a refractive index of 1.43) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40 and dried for 2 minutes at 120° C. Finally, a coating layer having a thickness of about 30 μm was obtained.

### Example 3

53.2 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 11.13 grams of a solvent (butyl acetate) and 26.6 grams of organic particles (Tospearl 145 A, provided by Momentive Company, silicone resin solid spherical particles with a mean particle size of 4.5 μm and a refractive index of 1.43) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40 and dried for 2 minutes at 150° C. Finally, a coating layer having a thickness of about 30 μm was obtained.

### Example 4

53.2 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 11.13 grams of a solvent (butyl acetate) and 26.6 grams of organic particles (SSX-105, provided by Sekisui Company, polymethacrylate resin solid spherical particles with a mean particle size of 5 μm and a refractive index of 1.49) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40 and dried for 2 minutes at 150° C. Finally, a coating layer having a thickness of about 30 μm was obtained.

### Example 5

29.56 grams of an acrylate resin (a mixture of 90 wt % of butyl acrylate monomers and 10 wt % of hyperbranched polyester acrylate oligomers (Etercure 6361-100, provided by Eternal Chemical Co. Ltd., with a solids content of 100% and a refractive index of 1.425)) were added into a plastic bottle, then 40 grams of a solvent (butyl acetate) and 29.56 grams of organic particles (SSX-105, provided by Sekisui Company, polymethacrylate resin solid spherical particles with a mean particle size of 5 μm and a refractive index of 1.49) were sequentially added under high speed stirring, and finally 0.88 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #40, dried for 2 minutes at 120° C. and then irradiated with UV light (irradiation intensity: 500 mJ/cm²). Finally, a coating layer having a thickness of about 30 μm was obtained.

### Example 6

The steps in Example 3 were repeated except that Tospearl 120A (provided by Momentive Company, silicone resin solid spherical particles with a mean particle size of 2 μm and a refractive index of 1.43) was used as organic particles.

### Example 7

The steps in Example 3 were repeated except that Tospearl 3000A (provided by Momentive Company, silicone resin solid spherical particles with a mean particle size of 4˜7 μm and a refractive index of 1.43) was used as organic particles.

### Example 8

The steps in Example 3 were repeated except that Tospearl 3120 (provided by Momentive Company, silicone resin solid spherical particles with a mean particle size of 12 μm and a refractive index of 1.43) was used as organic particles.

### Example 9

72.48 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 0.67 grams of a solvent (butyl acetate) and 14.5 grams of organic particles (Tospearl 145A, provided by Momentive Company, silicone resin solid spherical particles with a mean particle size of 4.5 μm and a refractive index of 1.43) were sequentially added under high speed stirring, and finally 12.35 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #20 and dried for 2 minutes at 150° C. Finally, a coating layer having a thickness of about 10 μm was obtained.

### Example 10

The steps in Example 9 were repeated except that an RDS Bar Coater #30 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 20 μm was obtained.

### Example 11

The steps in Example 9 were repeated except that an RDS Bar Coater #40 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 30 μm was obtained.

### Example 12

The steps in Example 9 were repeated except that an RDS Bar Coater #50 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 50 μm was obtained.

### Example 13

64.67 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 4.91 grams of a solvent (butyl acetate) and 19.4 grams of organic particles (Tospearl 145 A, provided by Momentive Company, silicone resin solid spherical particles with a mean particle size of 4.5 μm and a refractive index of 1.43) were sequentially added under high speed stirring, and finally 11.02 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #10 and dried for 2 minutes at 150° C. Finally, a coating layer having a thickness of about 5 μm was obtained.

### Example 14

The steps in Example 13 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 10 μm was obtained.

### Example 15

The steps in Example 13 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 20 μm was obtained.

### Example 16

The steps in Example 13 were repeated except that an RDS Bar Coater #40 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 30 μm was obtained.

### Example 17

The steps in Example 13 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 50 μm was obtained.

### Example 18

The steps in Example 13 were repeated except that the amounts of the fluorocarbon resin, solvent, organic particles and curing agent were changed to 58.37 grams, 8.33 grams, 23.35 grams and 9.95 grams, respectively.

### Example 19

The steps in Example 14 were repeated except that the amounts of the fluorocarbon resin, solvent, organic particles and curing agent were changed to 58.37 grams, 8.33 grams, 23.35 grams and 9.95 grams, respectively.

### Example 20

The steps in Example 15 were repeated except that the amounts of the fluorocarbon resin, solvent, organic particles and curing agent were changed to 58.37 grams, 8.33 grams, 23.35 grams and 9.95 grams, respectively.

### Example 21

The steps in Example 16 were repeated except that the amounts of the fluorocarbon resin, solvent, organic particles and curing agent were changed to 58.37 grams, 8.33 grams, 23.35 grams and 9.95 grams, respectively.

### Example 22

The steps in Example 17 were repeated except that the amounts of the fluorocarbon resin, solvent, organic particles and curing agent were changed to 58.37 grams, 8.33 grams, 23.35 grams and 9.95 grams, respectively.

### Example 23

The steps in Example 13 were repeated except that the amounts of the fluorocarbon resin, solvent, organic particles and curing agent were changed to 53.2 grams, 11.13 grams, 26.6 grams and 9.07 grams, respectively.

### Example 24

The steps in Example 14 were repeated except that the amounts of the fluorocarbon resin, solvent, organic particles and curing agent were changed to 53.2 grams, 11.13 grams, 26.6 grams and 9.07 grams, respectively.

### Example 25

The steps in Example 15 were repeated except that the amounts of the fluorocarbon resin, solvent, organic particles and curing agent were changed to 53.2 grams, 11.13 grams, 26.6 grams and 9.07 grams, respectively.

### Example 26

The steps in Example 17 were repeated except that the amounts of the fluorocarbon resin, solvent, organic particles and curing agent were changed to 53.2 grams, 11.13 grams, 26.6 grams and 9.07 grams, respectively.

### Example 27

The steps in Example 13 were repeated except that the amounts of the fluorocarbon resin, solvent, organic particles and curing agent were changed to 42.02 grams, 17.2 grams, 33.62 grams and 7.16 grams, respectively.

### Example 28

The steps in Example 14 were repeated except that the amounts of the fluorocarbon resin, solvent, organic particles and curing agent were changed to 42.02 grams, 17.2 grams, 33.62 grams and 7.16 grams, respectively.

### Example 29

The steps in Example 15 were repeated except that the amounts of the fluorocarbon resin, solvent, organic particles and curing agent were changed to 42.02 grams, 17.2 grams, 33.62 grams and 7.16 grams, respectively.

### Example 30

The steps in Example 16 were repeated except that the amounts of the fluorocarbon resin, solvent, organic particles and curing agent were changed to 42.02 grams, 17.2 grams, 33.62 grams and 7.16 grams, respectively.

### Example 31

The steps in Example 17 were repeated except that the amounts of the fluorocarbon resin, solvent, organic particles and curing agent were changed to 42.02 grams, 17.2 grams, 33.62 grams and 7.16 grams, respectively.

### Example 32

The steps in Example 13 were repeated except that the amounts of the fluorocarbon resin, solvent, organic particles and curing agent were changed to 39.27 grams, 18.69 grams, 35.35 grams and 6.69 grams, respectively.

### Example 33

The steps in Example 14 were repeated except that the amounts of the fluorocarbon resin, solvent, organic particles and curing agent were changed to 39.27 grams, 18.69 grams, 35.35 grams and 6.69 grams, respectively.

### Example 34

The steps in Example 15 were repeated except that the amounts of the fluorocarbon resin, solvent, organic particles and curing agent were changed to 39.27 grams, 18.69 grams, 35.35 grams and 6.69 grams, respectively.

### Example 35

The steps in Example 16 were repeated except that the amounts of the fluorocarbon resin, solvent, organic particles and curing agent were changed to 39.27 grams, 18.69 grams, 35.35 grams and 6.69 grams, respectively.

### Example 36

The steps in Example 17 were repeated except that the amounts of the fluorocarbon resin, solvent, organic particles and curing agent were changed to 39.27 grams, 18.69 grams, 35.35 grams and 6.69 grams, respectively.

### Example 37

The steps in Example 13 were repeated except that the amounts of the fluorocarbon resin, solvent, organic particles and curing agent were changed to 36.86 grams, 20 grams, 36.86 grams and 6.28 grams, respectively.

### Example 38

The steps in Example 14 were repeated except that the amounts of the fluorocarbon resin, solvent, organic particles and curing agent were changed to 36.86 grams, 20 grams, 36.86 grams and 6.28 grams, respectively.

### Example 39

The steps in Example 15 were repeated except that the amounts of the fluorocarbon resin, solvent, organic particles and curing agent were changed to 36.86 grams, 20 grams, 36.86 grams and 6.28 grams, respectively.

### Example 40

The steps in Example 16 were repeated except that the amounts of the fluorocarbon resin, solvent, organic particles and curing agent were changed to 36.86 grams, 20 grams, 36.86 grams and 6.28 grams, respectively.

### Example 41

The steps in Example 17 were repeated except that the amounts of the fluorocarbon resin, solvent, organic particles and curing agent were changed to 36.86 grams, 20 grams, 36.86 grams and 6.28 grams, respectively.

### Example 42

64.67 grams of an acrylate resin (ETERAC 7363-TS-50, provided by Eternal Chemical Co. Ltd., an acrylate copolymer resin with a solids content of 50% and a refractive index of 1.49) were added into a plastic bottle, then 4.91 grams of a solvent (butyl acetate) and 19.4 grams of organic particles (Tospearl 145A, provided by Momentive Company, silicone resin solid spherical particles with a mean particle size of 4.5 μm and a refractive index of 1.43) were sequentially added under high speed stirring, and finally 11.02 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #10 and dried for 2 minutes at 120° C. Finally, a coating layer having a thickness of about 5 μm was obtained.

### Example 43

The steps in Example 42 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 10 μm was obtained.

### Example 44

The steps in Example 42 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 20 μm was obtained.

### Example 45

The steps in Example 42 were repeated except that an RDS Bar Coater #40 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 30 μm was obtained.

### Example 46

The steps in Example 42 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 50 μm was obtained.

### Example 47

The steps in Example 42 were repeated except that the amounts of the resin, solvent, organic particles and curing agent were changed to 53.2 grams, 11.13 grams, 26.6 grams and 9.07 grams, respectively.

### Example 48

The steps in Example 43 were repeated except that the amounts of the resin, solvent, organic particles and curing agent were changed to 53.2 grams, 11.13 grams, 26.6 grams and 9.07 grams, respectively.

### Example 49

The steps in Example 44 were repeated except that the amounts of the resin, solvent, organic particles and curing agent were changed to 53.2 grams, 11.13 grams, 26.6 grams and 9.07 grams, respectively.

### Example 50

The steps in Example 46 were repeated except that the amounts of the resin, solvent, organic particles and curing agent were changed to 53.2 grams, 11.13 grams, 26.6 grams and 9.07 grams, respectively.

### Example 51

The steps in Example 42 were repeated except that the amounts of the resin, solvent, organic particles and curing agent were changed to 42.02 grams, 17.2 grams, 33.62 grams and 7.16 grams, respectively.

### Example 52

The steps in Example 43 were repeated except that the amounts of the resin, solvent, organic particles and curing agent were changed to 42.02 grams, 17.2 grams, 33.62 grams and 7.16 grams, respectively.

### Example 53

The steps in Example 44 were repeated except that the amounts of the resin, solvent, organic particles and curing agent were changed to 42.02 grams, 17.2 grams, 33.62 grams and 7.16 grams, respectively.

### Example 54

The steps in Example 45 were repeated except that the amounts of the resin, solvent, organic particles and curing agent were changed to 42.02 grams, 17.2 grams, 33.62 grams and 7.16 grams, respectively.

### Example 55

The steps in Example 46 were repeated except that the amounts of the resin, solvent, organic particles and curing agent were changed to 42.02 grams, 17.2 grams, 33.62 grams and 7.16 grams, respectively.

### Example 56

36.81 grams of an epoxy acrylate resin (SUP-560, provided by Shin-A Company, with a solids content of 100% and a refractive index of 1.57) were added into a plastic bottle, then 40 grams of a solvent (butyl acetate) and 22.09 grams of organic particles (SSX-105, provided by Sekisui Company, polymethacrylate resin solid spherical particles with a mean particle size of 5 μm and a refractive index of 1.49) were sequentially added under high speed stirring, and finally 1.10 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #10, dried for 2 minutes at 120° C. and then irradiated with UV light (irradiation intensity: 500 mJ/cm²). Finally, a coating layer having a thickness of about 5 μm was obtained.

### Example 57

The steps in Example 56 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. and then irradiated with UV light (irradiation intensity: 500 mJ/cm²). Finally, a coating layer having a thickness of about 10 μm was obtained.

### Example 58

The steps in Example 56 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. and then irradiated with UV light (irradiation intensity: 500 mJ/cm²). Finally, a coating layer having a thickness of about 20 μm was obtained.

### Example 59

The steps in Example 56 were repeated except that an RDS Bar Coater #40 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. and then irradiated with UV light (irradiation intensity: 500 mJ/cm²). Finally, a coating layer having a thickness of about 30 μm was obtained.

### Example 60

The steps in Example 56 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 120° C. and then irradiated with UV light (irradiation intensity: 500 mJ/cm²). Finally, a coating layer having a thickness of about 50 μm was obtained.

### Example 61

The steps in Example 56 were repeated except that the amounts of the resin, solvent, organic particles and photo-initiator were changed to 29.56 grams, 40 grams, 29.56 grams and 0.88 grams, respectively.

### Example 62

The steps in Example 57 were repeated except that the amounts of the resin, solvent, organic particles and photo-initiator were changed to 29.56 grams, 40 grams, 29.56 grams and 0.88 grams, respectively.

### Example 63

The steps in Example 58 were repeated except that the amounts of the resin, solvent, organic particles and photo-initiator were changed to 29.56 grams, 40 grams, 29.56 grams and 0.88 grams, respectively.

### Example 64

The steps in Example 60 were repeated except that the amounts of the resin, solvent, organic particles and photo-initiator were changed to 29.56 grams, 40 grams, 29.56 grams and 0.88 grams, respectively.

### Example 65

The steps in Example 56 were repeated except that the amounts of the resin, solvent, organic particles and curing agent were changed to 22.82 grams, 40 grams, 36.5 grams and 0.68 grams, respectively.

### Example 66

The steps in Example 57 were repeated except that the amounts of the resin, solvent, organic particles and photo-initiator were changed to 22.82 grams, 40 grams, 36.5 grams and 0.68 grams, respectively.

### Example 67

The steps in Example 58 were repeated except that the amounts of the resin, solvent, organic particles and photo-initiator were changed to 22.82 grams, 40 grams, 36.5 grams and 0.68 grams, respectively.

### Example 68

The steps in Example 59 were repeated except that the amounts of the resin, solvent, organic particles and photo-initiator were changed to 22.82 grams, 40 grams, 36.5 grams and 0.68 grams, respectively.

### Example 69

The steps in Example 60 were repeated except that the amounts of the resin, solvent, organic particles and photo-initiator were changed to 22.82 grams, 40 grams, 36.5 grams and 0.68 grams, respectively.

### Example 70

64.67 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 4.91 grams of a solvent (butyl acetate) and 19.4 grams of organic particles (SSX-105, provided by Sekisui Company, polymethacrylate resin solid spherical particles with a mean particle size of 5 μm and a refractive index of 1.49) were sequentially added under high speed stirring, and finally 11.02 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #20 and dried for 2 minutes at 150° C. Finally, a coating layer having a thickness of about 10 μm was obtained.

### Example 71

The steps in Example 70 were repeated except that an RDS Bar Coater #30 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 20 μm was obtained.

### Example 72

The steps in Example 70 were repeated except that an RDS Bar Coater #40 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 30 μm was obtained.

### Example 73

The steps in Example 70 were repeated except that an RDS Bar Coater #50 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 50 μm was obtained.

### Example 74

53.2 grams of a fluorocarbon resin (Eterflon 4101-50, provided by Eternal Chemical Co. Ltd., a trifluorochloroethylene and alkyl vinyl ether copolymer resin with a solids content of 50% and a refractive index of 1.47) were added into a plastic bottle, then 11.13 grams of a solvent (butyl acetate) and 26.6 grams of organic particles (SSX-105, provided by Sekisui Company, polymethacrylate resin solid spherical particles with a mean particle size of 5 μm and a refractive index of 1.49) were sequentially added under high speed stirring, and finally 9.07 grams of a curing agent (Desmodur 3390, provided by Bayer Corporation, an isocyanate curing agent with a solids content of about 75%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #10 and dried for 2 minutes at 150° C. Finally, a coating layer having a thickness of about 5 μm was obtained.

### Example 75

The steps in Example 74 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 10 μm was obtained.

### Example 76

The steps in Example 74 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 20 μm was obtained.

### Example 77

The steps in Example 74 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 50 μm was obtained.

### Example 78

The steps in Example 74 were repeated except that the amounts of the resin, solvent, organic particles and curing agent were changed to 42.02 grams, 17.2 grams, 33.62 grams and 7.16 grams, respectively.

### Example 79

The steps in Example 78 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 10 μm was obtained.

### Example 80

The steps in Example 78 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 20 μm was obtained.

### Example 81

The steps in Example 78 were repeated except that an RDS Bar Coater #40 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 30 μm was obtained.

### Example 82

The steps in Example 78 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation) and dried for 2 minutes at 150° C. Finally, a coating layer having a thickness of about 50 μm was obtained.

### Example 83

36.81 grams of an acrylate resin (a mixture of 90 wt % of butyl acrylate monomers and 10 wt % of hyperbranched polyester acrylate oligomers (Etercure 6361-100, provided by Eternal Chemical Co. Ltd., with a solids content of 100% and a refractive index of 1.425)) were added into a plastic bottle, then 40 grams of a solvent (butyl acetate) and 22.09 grams of organic particles (SSX-105, provided by Sekisui Company, polymethacrylate resin solid spherical particles with a mean particle size of 5 μm and a refractive index of 1.49) were sequentially added under high speed stirring, and finally 1.1 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #20, dried for 2 minutes at 120° C. and then irradiated with UV light (irradiation intensity: 500 mJ/cm²). Finally, a coating layer having a thickness of about 10 μm was obtained.

### Example 84

The steps in Example 83 were repeated except that an RDS Bar Coater #30 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 20 μm was obtained.

### Example 85

The steps in Example 83 were repeated except that an RDS Bar Coater #40 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 30 μm was obtained.

### Example 86

The steps in Example 83 were repeated except that an RDS Bar Coater #50 was used in place of an RDS Bar Coater #20. The coating composition was coated on one side of a polyethylene terephthalate (PET) film (CH885, with a thickness of 250 μm, provided by NAN YA Plastics Corporation) and dried for 2 minutes at 120° C. Finally, a coating layer having a thickness of about 50 μm was obtained.

### Example 87

29.56 grams of an acrylate resin (a mixture of 90 wt % of butyl acrylate monomers and 10 wt % of hyperbranched polyester acrylate oligomers (Etercure 6361-100, provided by Eternal Chemical Co. Ltd., with a solids content of 100% and a refractive index of 1.425)) were added into a plastic bottle, then 40 grams of a solvent (butyl acetate) and 29.56 grams of organic particles (SSX-105, provided by Sekisui Company, polymethacrylate resin solid spherical particles with a mean particle size of 5 μm and a refractive index of 1.49) were sequentially added under high speed stirring, and finally 0.88 grams of a photo-initiator (Irgacure 184, provided by Ciba Company, with a solids content of about 100%) were added, so as to prepare a coating composition with a solids content of about 60% and a total weight of about 100 grams. The coating composition was coated on one side of a polyethylene terephthalate (PET) film (CH885, with a thickness of 250 μm, provided by NAN YA Plastics Corporation) with an RDS Bar Coater #10, dried for 2 minutes at 120° C. and then irradiated with UV light (irradiation intensity: 500 mJ/cm²). Finally, a coating layer having a thickness of about 5 μm was obtained.

### Example 88

The steps in Example 87 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 10 μm was obtained.

### Example 89

The steps in Example 87 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 20 μm was obtained.

### Example 90

The steps in Example 87 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 50 μm was obtained.

### Example 91

The steps in Example 87 were repeated except that the amounts of the resin, solvent, organic particles and photo-initiator were changed to 22.82 grams, 40 grams, 36.5 grams and 0.68 grams, respectively.

### Example 92

The steps in Example 91 were repeated except that an RDS Bar Coater #20 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 10 μm was obtained.

### Example 93

The steps in Example 91 were repeated except that an RDS Bar Coater #30 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 20 μm was obtained.

### Example 94

The steps in Example 91 were repeated except that an RDS Bar Coater #40 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 30 μm was obtained.

### Example 95

The steps in Example 91 were repeated except that an RDS Bar Coater #50 was used in place of an RDS Bar Coater #10. The coating composition was coated on one side of a polyethylene terephthalate (PET) film (CH885, with a thickness of 250 μm, provided by NAN YA Plastics Corporation), dried for 2 minutes at 120° C. and then irradiated with UV light (irradiation intensity: 500 mJ/cm²). Finally, a coating layer having a thickness of about 50 μm was obtained.

<Data Test Method>

1. Test of total light transmittance (Tt): Measurement is carried out with a coating surface facing a light incident direction at a test wavelength of 550 nm according to the ASTM E903-96 standard method by using a Lamda 650S UV-Visible Light Spectrometer (Perkin Elmer Inc.) with a 60 mm integrating sphere as a detector, to obtain the total light transmittance Tt.

2. Test of parallel light transmittance (Pt): Measurement is carried out with a coating surface facing a light incident direction according to the JIS K7136 standard method by using a NDH 5000W Haze meter (Nippon Denshoku Industries Co., Ltd.), to obtain the parallel light transmittance (Pt).

3. Test of solar cell module efficiency (η): The solar cell module to be tested is irradiated at an illumination of AM 1.5 by using a solar simulator (Model: 92193A-1000, Newport Corporation), and an I-V characteristic curve is obtained, so as to calculate the solar cell module efficiency (η=Pmax/Pin).

4. Measurement of refractive index of a resin before being cured: the refractive index of the resin is measured by using an Abbe refractor (Model: DR-A1, ATAGO Corporation) (resin used in Example 5, and Examples 83-95: refractive index 1.425; Eterflon 4101-50: refractive index 1.47; Eterac 7363-TS-50: refractive index 1.49; and SUP-560: refractive index 1.57)

<Preparation of Solar Cell Module>

### Module Example 1

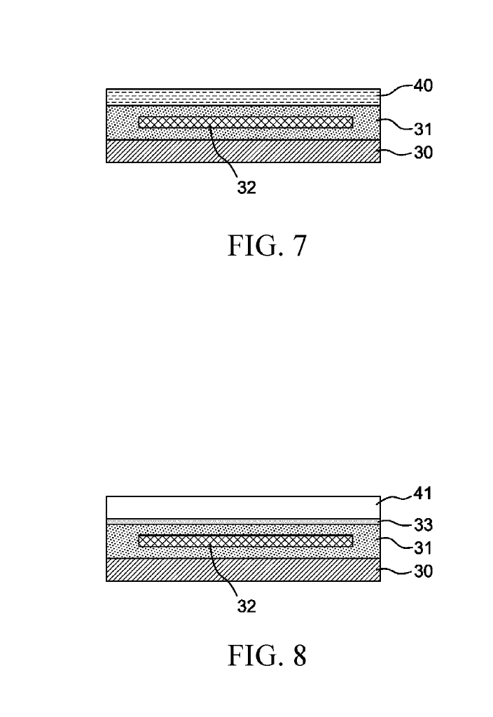

A solar cell module A as shown in FIG. 7 was prepared by laminating in sequence a tempered glass 40 (Sunmax™ protection glass, Asahi Glass Corporation), an encapsulant EVA resin 31 (SOLAR EVA, Mitsui Fabro Inc.), a monocrystalline silicon solar cell unit 32 (GIN156S, GINTECH Corporation, having a size of 52 mm×20 mm), an encapsulant EVA resin 31, and a backsheet 30 (YK-820, Eternal Corporation) with a vacuum laminator, so as to obtain the solar cell module.

### Module Example 2

A solar cell module A1 as shown in FIG. 8 was prepared by laminating in sequence an encapsulant EVA resin 31 (SOLAR EVA, Mitsui Fabro Inc.), a monocrystalline silicon solar cell unit 32 (GIN156S, GINTECH Corporation, having a size of 52 mm×20 mm), an encapsulant EVA resin 31 and a backsheet 30 (YK-820, Eternal Corporation) with a vacuum laminator, and then attaching a transparent PET film 41 of Comparative Example 2 to the surface of the encapsulant with an optical adhesive 33 (AO-805, Eternal Corporation), so as to obtain the solar cell module.

### Module Example 3

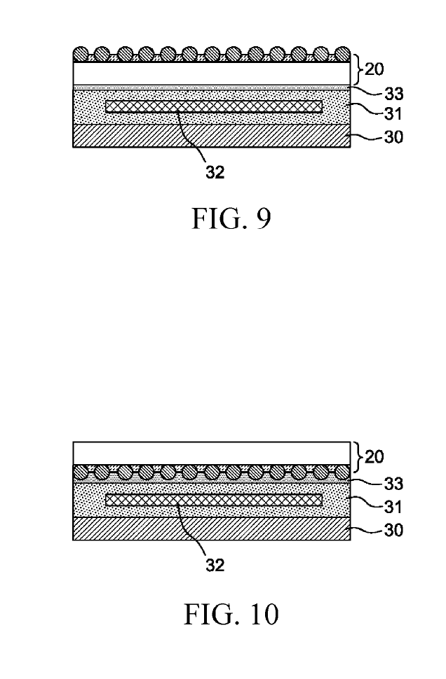

A solar cell module A2 as shown in FIG. 9 was prepared by repeating the steps of Module Example 2, except that the film of Comparative Example 2 was replaced by the film 20 of Comparative Example 3 (with the coating layer facing upward).

### Module Example 4

A solar cell module A3 as shown in FIG. 10 was prepared by repeating the steps in Module Example 2, except that the film of the Comparative Example 2 was replaced by the film 20 of the Comparative Example 3 (with the coating layer facing downward).

### Module Examples 5, 7, 9, 11, 13, 15, 17, and 19

The steps in Module Example 3 were repeated, except that the film of Comparative Example 3 was replaced by the films of Comparative Examples 4 to 6 and Examples 1 to 5, and the coating layers were facing upward.

### Module Examples 6, 8, 10, 12, 14, 16, 18, and 20

The steps in Module Example 4 were repeated, except that the film of Comparative Example 3 was replaced by the films of Comparative Examples 4 to 6 and Examples 1 to 5, and the coating layers were facing downward.

TABLE 1
Relation between n_{B}, α value, and η of the transmittance enhancement film

| Transmittance Enhancement Film | | | | | | | | |
|---|---|---|---|---|---|---|---|---|
| | Organic | | | | Cell Module | | | |
| | Particle | | | | | | Power | |
| | Refractive | | | | | | generation | Gain in Power |
| Film | Index | | | | Module | | efficiency | Generation |
| Example | n_{B} | α | Tt (%) | Pt (%) | Example No. | Module | η (%) | Efficiency Δη |
| Comparative | — | — | 90.61 | 93.95 | 1 | A | 17.05 | 0 |
| Example 1 | | | | | | | | |
| Comparative | — | — | 91.77 | 91.42 | 2 | A1 | 17.06 | 0.01 |
| Example 2 | | | | | | | | |
| Comparative | 1.43 | 0.91 | 92.13 | 6.48 | 3 | A2 | 17.16 | 0.11 |
| Example 3 | | | | | 4 | A3 | 16.51 | −0.54 |
| Comparative | 1.59 | 1.01 | 76.18 | 5.23 | 5 | A2 | 16.42 | −0.63 |
| Example 4 | | | | | 6 | A3 | 16.37 | −0.68 |
| Comparative | 1.59 | 1.07 | 90.98 | 2.75 | 7 | A2 | 17.04 | −0.01 |
| Example 5 | | | | | 8 | A3 | 17.03 | −0.02 |
| Comparative | 1.59 | 1.08 | 88.81 | 1.63 | 9 | A2 | 16.91 | −0.14 |
| Example 6 | | | | | 10 | A3 | 16.90 | −0.15 |
| Example 1 | 1.49 | 0.95 | 101.1 | 7.06 | 11 | A2 | 17.40 | 0.35 |
| | | | | | 12 | A3 | 17.39 | 0.34 |
| Example 2 | 1.43 | 0.96 | 98.47 | 7.51 | 13 | A2 | 17.36 | 0.31 |
| | | | | | 14 | A3 | 17.41 | 0.36 |
| Example 3 | 1.43 | 0.97 | 99.05 | 4.91 | 15 | A2 | 17.32 | 0.27 |
| | | | | | 16 | A3 | 17.30 | 0.25 |
| Example 4 | 1.49 | 1.01 | 96.60 | 11.73 | 17 | A2 | 17.27 | 0.22 |
| | | | | | 18 | A3 | 17.26 | 0.21 |
| Example 5 | 1.49 | 1.05 | 95.81 | 7.29 | 19 | A2 | 17.23 | 0.18 |
| | | | | | 20 | A3 | 17.22 | 0.17 |

Note:
B/R = 1.0, coating thickness = 30 μm

Table 1 shows the module power generation efficiency (η) and the gain in module power generation efficiency (Δη) of solar cell module Examples 1 to 20 and the organic particle refractive index (n_{B}), the α value, and the optical properties, in which the gain in power generation efficiency (Δη) is the difference between the power generation efficiency of the solar cell module A1, A2, or A3 and the power generation efficiency of the solar cell module A.

As shown in Examples 1 to 5 in Table 1, when the transmittance enhancement film meets the conditions that 0.95≦α≦1.05 and n_{B}<1.5, the total light transmittance (Tt) of the transmittance enhancement film is higher than 95%, and the parallel light transmittance (Pt) is less than 12%, indicating that after the light passes through the transmittance enhancement film and enters the module, more internal total reflection is caused, thereby improving the light utilization, and when the transmittance enhancement film is assembled on a light incident surface of a solar cell module, the corresponding module power generation efficiency η is higher than those of all Comparative Examples.

As shown in Comparative Examples 3 to 6 in Table 1, when the α value of the transmittance enhancement film falls outside the range of 0.95≦α≦1.05 (Comparative Example 3, Comparative Example 5, and Comparative Example 6), or n_{B} of the transmittance enhancement film >1.5 (Comparative Examples 4 to 6), the total light transmittance of the transmittance enhancement film is less than 95%, and when the transmittance enhancement film is assembled on a light incident surface of a solar cell module, the corresponding module power generation efficiency η is less than those of the embodiments.

### Module Example 21

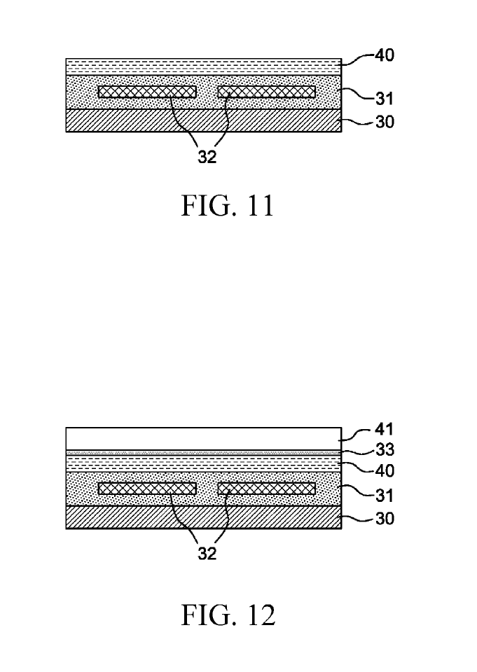

A solar cell module B as shown in FIG. 11 was prepared by laminating in sequence the tempered glass 40 (Sunmax™ protection glass, Asahi Glass Corporation) of Comparative Example 1, the encapsulant EVA resin 31 (SOLAR EVA, Mitsui Fabro Inc.), the monocrystalline silicon solar cell unit 32 (GIN156S, GINTECH Corporation, formed with two silicon chips having a size of 52 mm×9 mm and 2 mm spaced from each other by welding in series with two longer sides parallel to each other), the encapsulant EVA resin 31 and the backsheet 30 (YK-820, Eternal Corporation) with a vacuum laminator, as so to obtain the solar cell module.

### Module Example 22

A solar cell module C as shown in FIG. 12 was prepared by attaching the transparent PET film 41 of Comparative Example 2 onto the glass of Module Example 21 with the optical adhesive 33 (AO-805, Eternal Corporation), so as to obtain a solar cell module.

### Module Example 23

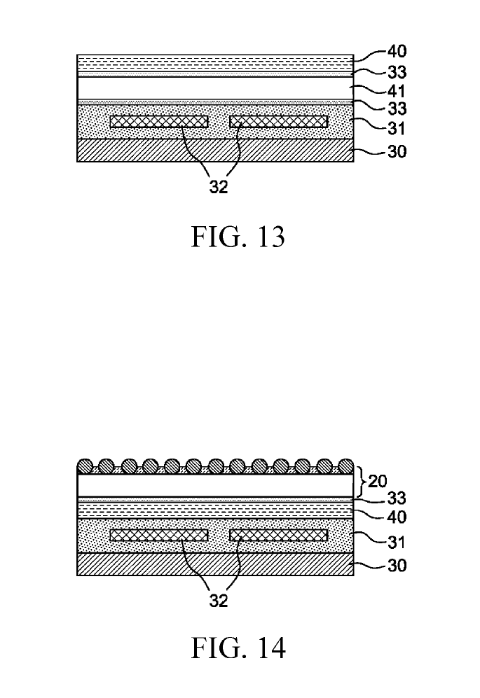

A solar cell module D as shown in FIG. 13 was prepared by laminating in sequence the encapsulant EVA resin 31 (SOLAR EVA, Mitsui Fabro Inc.), the monocrystalline silicon solar cell unit 32 (GIN156S, GINTECH Corporation, formed with two silicon chips having a size of 52 mm×9 mm and 2 mm spaced from each other by welding in series with two longer sides parallel to each other), the encapsulant EVA resin 31, and the backsheet 30 (YK-820, Eternal Corporation) with a vacuum laminator, and then attaching in sequence the transparent PET film 41 of Comparative Example 2 and the tempered glass 40 (Sunmax™ protection glass, Asahi Glass Corporation) to the surface of the encapsulant with the optical adhesive 33 (AO-805, Eternal Corporation), so as to obtain the solar cell module.

### Module Examples 24, 28, 32, and 36

Solar cell assemblies C1 as shown in FIG. 14 were prepared by respectively attaching the films 20 of Comparative Example 3, Comparative Example 4, Comparative Example 6, and Example 2 onto the glass 40 of Module Example 21 with the optical adhesive 33 (AO-805, Eternal Corporation), with the coating layers facing upward, so as to obtain the solar cell assemblies.

### Module Examples 25, 29, 33, and 37

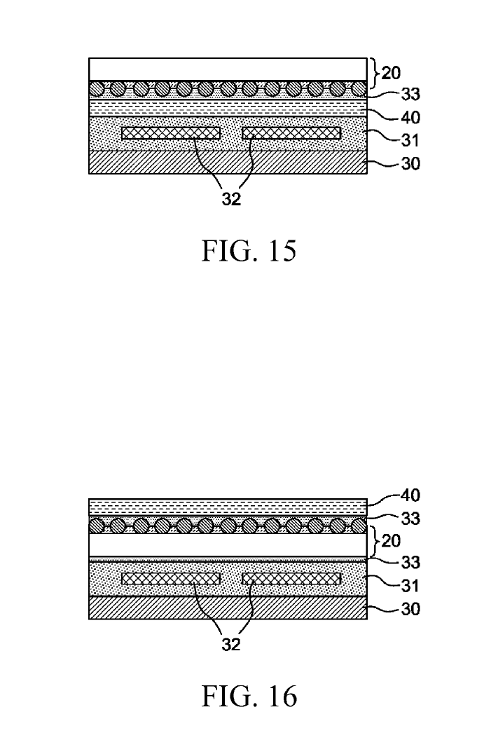

Solar cell assemblies C2 as shown in FIG. 15 were prepared by respectively attaching the films 20 of Comparative Example 3, Comparative Example 4, Comparative Example 6, and Embodiment 2 were respectively attached on the glass 40 of Module Example 21 with the optical adhesive 33 (AO-805, Eternal Corporation), with the coating layers facing downward, so as to obtain the solar cell assemblies.

### Module Example 26

A solar cell module D1 as shown in FIG. 16 was prepared by repeating the steps in Module Example 23, except that the film 41 of Comparative Example 2 was replaced by the film 20 of the Comparative Example 3 (with the coating layer facing upward).

### Module Example 27

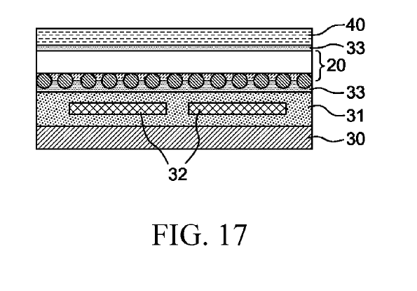

A solar cell module D2 as shown in FIG. 17 was prepared by repeating the steps in Module Example 23, except that the film 41 of Comparative Example 2 was replaced by the film 20 of Comparative Example 3 (with the coating layer facing downward).

### Module Examples 30, 34, and 38

The steps in Module Example 26 were repeated, excepted that the film of Comparative Example 3 was replaced by the films of Comparative Example 4, Comparative Example 6, and Embodiment 2 respectively.

### Module Examples 31, 35, and 39

The steps in Module Example 27 were repeated, excepted that the film of Comparative Example 3 was replaced by the films of Comparative Example 4, Comparative Example 6, and Example 2 respectively.

TABLE 2
Relation between n_{B}, α value, and η of the transmittance enhancement film

| Transmittance enhancement film | | | | | | | | |
|---|---|---|---|---|---|---|---|---|
| | Organic | | | | Cell Module | | | |
| | Particle | | | | | | Power | |
| | Refractive | | | | | | Generation | Gain in Power |
| Film | Index | | | | Module | | Efficiency | Generation |
| Example | n_{B} | α | Tt (%) | Pt (%) | Example No. | Module | η (%) | Efficiency Δη |
| Comparative | — | — | 90.61 | 93.95 | 21 | B | 17.20 | 0 |
| Example 1 | | | | | | | | |
| Comparative | — | — | 91.77 | 91.42 | 22 | C | 17.21 | 0.01 |
| Example 2 | | | | | 23 | D | 17.21 | 0.01 |
| Comparative | 1.43 | 0.91 | 92.13 | 6.48 | 24 | C1 | 17.30 | 0.1 |
| Example 3 | | | | | 25 | C2 | 17.19 | −0.01 |
| | | | | | 26 | D1 | 17.04 | −0.16 |
| | | | | | 27 | D2 | 16.59 | −0.61 |
| Comparative | 1.59 | 1.01 | 76.18 | 5.23 | 28 | C1 | 16.63 | −0.57 |
| Example 4 | | | | | 29 | C2 | 16.62 | −0.58 |
| | | | | | 30 | D1 | 16.63 | −0.57 |
| | | | | | 31 | D2 | 16.38 | −0.82 |
| Comparative | 1.59 | 1.08 | 88.81 | 1.63 | 32 | C1 | 17.08 | −0.12 |
| Example 6 | | | | | 33 | C2 | 17.06 | −0.14 |
| | | | | | 34 | D1 | 17.14 | −0.06 |
| | | | | | 35 | D2 | 17.12 | −0.08 |
| Example 2 | 1.43 | 0.96 | 98.47 | 7.51 | 36 | C1 | 17.58 | 0.38 |
| | | | | | 37 | C2 | 17.61 | 0.41 |
| | | | | | 38 | D1 | 17.61 | 0.41 |
| | | | | | 39 | D2 | 17.56 | 0.36 |

Note:
B/R = 1.0, coating thickness = 30 μm

Table 2 shows the module power generation efficiency (η) and the gain in module power generation efficiency (Δη) of solar cell module Examples 21 to 39, and the organic particle refractive index (n_{B}), the α value, and the optical properties of the transmittance enhancement film used in the module. The B/R value and the α value are as defined above, and the gain in module power generation efficiency (Δη) is the difference between the power generation efficiency of the solar cell assemblies C, C1, C2, D, D1, or D2 and the power to generation efficiency of the solar cell module B.

In the solar cell assemblies C, C1, and C2 in Table 2, a transparent PET (C) or a transmittance enhancement film was attached onto a light incident surface of a tempered glass with the coating layer facing upward (C1) or downward (C2). Module Examples 36 and 37 respectively have the forms of Assemblies C1 and C2, and the used transmittance enhancement film meets the conditions 0.95≦α≦1.05 and n_{B}<1.5 (Film Example 2) at the same time. The results in Table 2 show that compared with the module examples using the films of Comparative Examples 1 to 4 or Comparative Example 6, Module Examples 36 and 37 have a higher power generation efficiency η.

In the solar cell assemblies D, D1, and D2 in Table 2, a transparent PET film was located on another side of the light incident surface of the tempered glass respectively, such that the film exists between the glass and the encapsulant (D); or a transmittance enhancement film was attached onto another side of the light incident surface of the tempered glass with the coating layer facing upward (D1) or downward (D2), such that the film exists between the glass and the encapsulant. Module Examples 38 and 39 respectively have the forms of Assemblies D1 and D2, and the used transmittance enhancement film meets the conditions 0.95≦α≦1.05 and n_{B}<1.5 (Film Example 2) at the same time. The results in Table 2 show that compared with the module examples using the films of Comparative Examples 1 to 4 or Comparative Example 6, Module Examples 38 and 39 have a higher module power generation efficiency η.

It can be known from the results in Tables 1 and 2 that in a solar module, use of the transmittance enhancement film meeting the conditions 0.95≦α≦1.05 and n_{B}<1.5 at the same time can greatly improve the power generation efficiency of the module; and the transmittance enhancement film can replace the frontsheet in the original solar module (for example, Assemblies A2 and A3), and adhered to the light incident surface of the glass frontsheet (for example, Assemblies C1 and C2), or adhered to another side of the light incident surface of the glass frontsheet.

### Module Examples 40 to 128

The steps in Module Example 3 were repeated, except that the film of Comparative Example 3 was replaced by the films of Examples 6 to 95 respectively, with the coating layer facing upward.

TABLE 3
Relation between particle size of organic particles contained in the transmittance enhancement film and η.

| Transmittance Enhancement film | | | | | | Cell Module | | | |
|---|---|---|---|---|---|---|---|---|---|
| | | Organic | | | | | | | Gain in |
| | | Particle | | | | | | Power | Power |
| | Particle | Refractive | | | | | | Generation | Generation |
| Film | Size | Index | | | | Module | | Efficiency | Efficiency |
| Example | (μm) | n_{B} | α | Tt (%) | Pt (%) | Example No. | Module | η (%) | Δη |
| Example 3 | 4.5 | 1.43 | 0.97 | 99.05 | 4.91 | 15 | A2 | 17.32 | 0.27 |
| Example 6 | 2 | | | 102.50 | 4.68 | 40 | | 17.58 | 0.53 |
| Example 7 | 4-7 | | | 101.50 | 16.33 | 41 | | 17.51 | 0.46 |
| Example 8 | 12 | | | 98.71 | 21.37 | 42 | | 17.29 | 0.24 |

Note:
B/R = 1.0, coating thickness = 30 μm, n_{B} = 1.43, α = 0.97

Table 3 shows the properties of the transmittance enhancement films prepared when the mean diameter of the organic particles is changed to be 2 μm (Example 6), and 4-7 μm (Example 7) with wide distribution, and 12 μm to (Example 8) while the B/R value (1.0), the coating thickness (30 μm), the particle refractive index (n_{B}=1.43), and the α value (0.97) are fixed, and the power generation efficiency and the gain in power generation efficiency (Δη) after the transmittance enhancement film is assembled on the solar cell module (Module A2). The B/R value and the α value are as defined above, and the gain in power generation efficiency (Δη) is the difference between the power generation efficiency of the solar cell module A2 and the power generation efficiency of the solar cell module A.

According to Table 3, when the transmittance enhancement film meets the conditions 0.95≦α≦1.05 and n_{B}<1.5, the module power generation efficiency is higher than a conventional solar cell module (Module Example 1; solar cell solar cell module A) and a solar cell module using a transmittance enhancement film with the α value outside the range of 0.95≦α≦1.05 or with n_{B}>1.5 (Module Examples 3, 5, 7, and 9).

TABLE 4
Relation between B/R value and coating thickness of the transmittance enhancement film and η

| | | | | | Cell Module | | | |
|---|---|---|---|---|---|---|---|---|
| | | | | | | | | Gain in |
| Transmittance Enhancement Film | | | | | | | Power | Power |
| | Coating | Coating | | | | | Generation | Generation |
| Film | Formulation | Thickness | | | Module | | Efficiency | Efficiency |
| Example | B/R | (μm) | Tt (%) | Pt (%) | Example No. | Module | η (%) | Δη |
| Example 9 | 0.4 | 10 | 93.95 | 24.56 | 43 | A2 | 17.20 | 0.15 |
| Example 10 | 0.4 | 20 | 96.82 | 16.38 | 44 | A2 | 17.27 | 0.22 |
| Example 11 | 0.4 | 30 | 97.81 | 13.42 | 45 | A2 | 17.30 | 0.25 |
| Example 12 | 0.4 | 50 | 98.97 | 10.21 | 46 | A2 | 17.32 | 0.27 |
| Example 13 | 0.6 | 5 | 94.14 | 37.51 | 47 | A2 | 17.21 | 0.16 |
| Example 14 | 0.6 | 10 | 94.39 | 14.78 | 48 | A2 | 17.23 | 0.18 |
| Example 15 | 0.6 | 20 | 96.10 | 8.65 | 49 | A2 | 17.27 | 0.22 |
| Example 16 | 0.6 | 30 | 96.89 | 6.55 | 50 | A2 | 17.30 | 0.25 |
| Example 17 | 0.6 | 50 | 97.57 | 5.21 | 51 | A2 | 17.31 | 0.26 |
| Example 18 | 0.8 | 5 | 93.97 | 35.56 | 52 | A2 | 17.20 | 0.15 |
| Example 19 | 0.8 | 10 | 94.44 | 15.10 | 53 | A2 | 17.23 | 0.18 |
| Example 20 | 0.8 | 20 | 94.87 | 9.88 | 54 | A2 | 17.24 | 0.19 |
| Example 21 | 0.8 | 30 | 98.70 | 7.94 | 55 | A2 | 17.31 | 0.26 |
| Example 22 | 0.8 | 50 | 99.34 | 6.80 | 56 | A2 | 17.33 | 0.28 |
| Example 23 | 1.0 | 5 | 94.50 | 25.14 | 57 | A2 | 17.22 | 0.17 |
| Example 24 | 1.0 | 10 | 94.95 | 14.26 | 58 | A2 | 17.24 | 0.19 |
| Example 25 | 1.0 | 20 | 98.35 | 6.30 | 59 | A2 | 17.31 | 0.26 |
| Example 3 | 1.0 | 30 | 99.05 | 4.91 | 15 | A2 | 17.32 | 0.27 |
| Example 26 | 1.0 | 50 | 99.78 | 2.17 | 60 | A2 | 17.36 | 0.31 |
| Example 27 | 1.6 | 5 | 100.7 | 7.64 | 61 | A2 | 17.48 | 0.43 |
| Example 28 | 1.6 | 10 | 99.85 | 4.21 | 62 | A2 | 17.44 | 0.39 |
| Example 29 | 1.6 | 20 | 98.70 | 5.35 | 63 | A2 | 17.34 | 0.29 |
| Example 30 | 1.6 | 30 | 98.39 | 4.10 | 64 | A2 | 17.33 | 0.28 |
| Example 31 | 1.6 | 50 | 97.92 | 3.53 | 65 | A2 | 17.31 | 0.26 |
| Example 32 | 1.8 | 5 | 107.1 | 5.91 | 66 | A2 | 17.71 | 0.66 |
| Example 33 | 1.8 | 10 | 106.3 | 3.17 | 67 | A2 | 17.70 | 0.65 |
| Example 34 | 1.8 | 20 | 105.2 | 3.16 | 68 | A2 | 17.67 | 0.62 |
| Example 35 | 1.8 | 30 | 105.1 | 3.11 | 69 | A2 | 17.67 | 0.62 |
| Example 36 | 1.8 | 50 | 102.4 | 2.12 | 70 | A2 | 17.57 | 0.52 |
| Example 37 | 2.0 | 5 | 106.6 | 4.34 | 71 | A2 | 17.70 | 0.65 |
| Example 38 | 2.0 | 10 | 103.1 | 2.44 | 71 | A2 | 17.66 | 0.61 |
| Example 39 | 2.0 | 20 | 103.3 | 2.49 | 72 | A2 | 17.66 | 0.61 |
| Example 40 | 2.0 | 30 | 102.2 | 2.29 | 73 | A2 | 17.58 | 0.53 |
| Example 41 | 2.0 | 50 | 101.4 | 2.07 | 74 | A2 | 17.52 | 0.47 |

Note:
n_{B} = 1.43, α = 0.97

Table 4 shows the properties of the transmittance enhancement films prepared when the B/R value and the coating thickness are changed while α=0.97 and n_{B}=1.43 are fixed, and the power generation efficiency η and the gain in power generation efficiency (Δη) when the transmittance enhancement film is assembled on the solar cell module (Module A2). The B/R value and the α value are as defined above, and the gain in module power generation efficiency (Δη) is the difference between the power generation efficiency of the solar cell module A2 and the power generation efficiency of the solar cell module A.

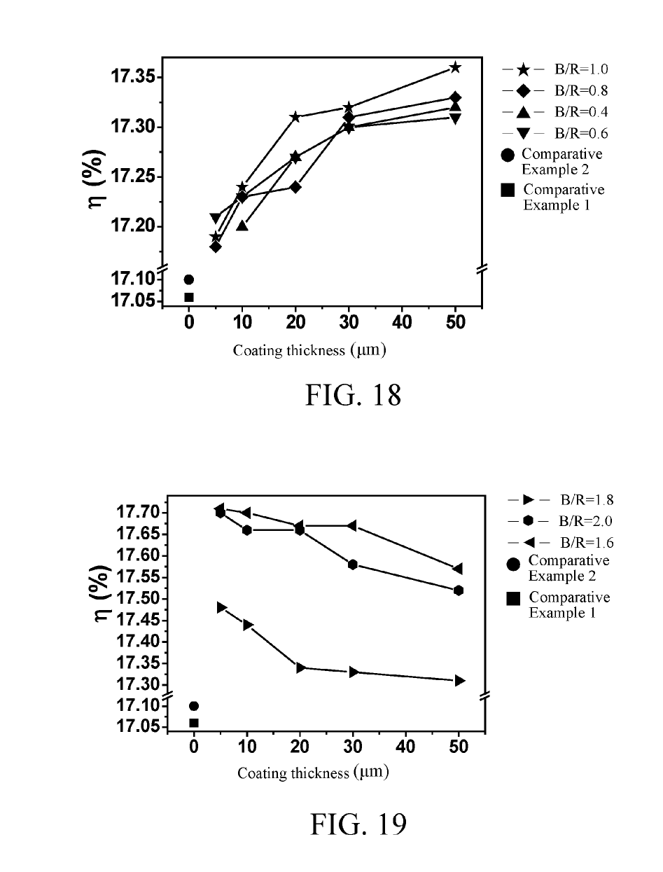

Film Examples and the results of the performance of the corresponding solar cell assemblies in Table 4 are as shown in FIGS. 18 and 19. FIG. 18 illustrates the influence of the coating thickness of the transmittance enhancement film (having a B/R value from 0.4 to 1.0) on the power generation efficiency η while α=0.97 and n_{B}=1.43 are fixed. FIG. 19 illustrates the influence of the coating thickness of the transmittance enhancement film (having a B/R value from 1.6 to 2.0) on the power generation efficiency η while α=0.97 and n_{B}=1.43 are fixed.

It can be seen from Table 4 and FIG. 18 that, while α=0.97 and n_{B}=1.43 are fixed, when the transmittance enhancement film of the present invention has a B/R value in the range from 0.4 to 1.0 (B/R=0.4: Examples 9-12; B/R=0.6: Examples 13-17; B/R=0.8 Examples 18-22; B/R=1.0: Examples 3 and 23-26), the total transmittance Tt and the power generation efficiency η obtained after the transmittance enhancement film is assembled into a solar cell module increase increase with the increase of the thickness of the transmittance enhancement film, and the efficiency is higher than the conventional solar cell module (Module Example 1; solar cell module A) and a solar cell module using a transmittance enhancement film with the a value outside the range of 0.95≦α≦1.05 or with n_{B}>1.5 (Module Examples 3, 5, 7, and 9).

Table 4 and FIG. 19 show that the transmittance enhancement film of the present invention has a B/R in the range from 1.6-2.0 (B/R=1.6: Examples 27-31; B/R=1.8: Examples 32-36; B/R=2.0: Examples 37-41), the total light transmittance Tt and the power generation efficiency η obtained after the to transmittance enhancement film is assembled into a solar cell module decrease with the increasing thickness of the transmittance enhancement film, but the efficiency is still higher than the conventional solar cell module (Module Example 1; solar cell module A) and a solar cell module using a transmittance enhancement film with the α value outside the range of 0.95≦α≦1.05 or with n_{B}>1.5 (Module Examples 3, 5, 7, and 9).

The results prove that when the solar cell module has a transmittance enhancement film meeting the conditions α=0.97 and n_{B}=1.43, when the B/R value of the transmittance enhancement film is less than 1.5, the thicker the coating layer of the transmittance enhancement film coating is (for example, 50 μm), the higher the module power generation efficiency will be; and when the B/R value of the transmittance enhancement film is equal to or greater than 1.5, the thinner the coating layer of the transmittance enhancement film (for example, 5 μm), the higher the module power generation efficiency will be.

TABLE 5
Relation between B/R value, coating thickness, n_{B} and α value of transmittance enhancement film and η

| Transmittance enhancement Film | | | | | | | Cell Module | | | |
|---|---|---|---|---|---|---|---|---|---|---|
| | | | Organic | | | | | | Module | Gain in |
| | | | Particle | | | | | | Power | Power |
| | Coating | Coating | Refractive | | | | | | Generation | Generation |
| Film | Formulation | Thickness | Index | | | | Module | | Efficiency | Efficiency |
| Example | B/R | (μm) | n_{B} | α | Tt (%) | Pt (%) | Example No. | Module | η (%) | Δη |
| Example 42 | 0.6 | 5 | 1.43 | 0.96 | 99.85 | 19.84 | 75 | A2 | 17.46 | 0.41 |
| Example 43 | 0.6 | 10 | 1.43 | 0.96 | 100.3 | 17.09 | 76 | A2 | 17.51 | 0.46 |
| Example 44 | 0.6 | 20 | 1.43 | 0.96 | 101.8 | 14.41 | 77 | A2 | 17.53 | 0.48 |
| Example 45 | 0.6 | 30 | 1.43 | 0.96 | 102.6 | 9.02 | 78 | A2 | 17.56 | 0.51 |
| Example 46 | 0.6 | 50 | 1.43 | 0.96 | 103.3 | 8.06 | 79 | A2 | 17.58 | 0.53 |
| Example 47 | 1.0 | 5 | 1.43 | 0.96 | 96.34 | 18.17 | 80 | A2 | 17.27 | 0.22 |
| Example 48 | 1.0 | 10 | 1.43 | 0.96 | 97.25 | 14.91 | 81 | A2 | 17.33 | 0.28 |
| Example 49 | 1.0 | 20 | 1.43 | 0.96 | 97.62 | 8.57 | 82 | A2 | 17.35 | 0.30 |
| Example 2 | 1.0 | 30 | 1.43 | 0.96 | 98.47 | 7.51 | 13 | A2 | 17.36 | 0.31 |
| Example 50 | 1.0 | 50 | 1.43 | 0.96 | 99.35 | 6.43 | 83 | A2 | 17.45 | 0.40 |
| Example 51 | 1.6 | 5 | 1.43 | 0.96 | 103.9 | 15.87 | 84 | A2 | 17.58 | 0.53 |
| Example 52 | 1.6 | 10 | 1.43 | 0.96 | 102.6 | 12.35 | 85 | A2 | 17.56 | 0.51 |
| Example 53 | 1.6 | 20 | 1.43 | 0.96 | 102.1 | 8.08 | 86 | A2 | 17.56 | 0.51 |
| Example 54 | 1.6 | 30 | 1.43 | 0.96 | 101.8 | 7.35 | 87 | A2 | 17.54 | 0.49 |
| Example 55 | 1.6 | 50 | 1.43 | 0.96 | 98.75 | 7.17 | 88 | A2 | 17.38 | 0.33 |
| Example 56 | 0.6 | 5 | 1.49 | 0.95 | 97.07 | 15.13 | 89 | A2 | 17.27 | 0.22 |
| Example 57 | 0.6 | 10 | 1.49 | 0.95 | 98.23 | 9.08 | 90 | A2 | 17.34 | 0.29 |
| Example 58 | 0.6 | 20 | 1.49 | 0.95 | 99.01 | 7.79 | 91 | A2 | 17.42 | 0.37 |
| Example 59 | 0.6 | 30 | 1.49 | 0.95 | 99.63 | 7.44 | 92 | A2 | 17.44 | 0.39 |
| Example 60 | 0.6 | 50 | 1.49 | 0.95 | 99.71 | 7.26 | 93 | A2 | 17.45 | 0.40 |
| Example 61 | 1.0 | 5 | 1.49 | 0.95 | 97.09 | 9.12 | 94 | A2 | 17.27 | 0.22 |
| Example 62 | 1.0 | 10 | 1.49 | 0.95 | 98.14 | 7.57 | 95 | A2 | 17.34 | 0.29 |
| Example 63 | 1.0 | 20 | 1.49 | 0.95 | 101.1 | 7.12 | 96 | A2 | 17.40 | 0.35 |
| Example 1 | 1.0 | 30 | 1.49 | 0.95 | 101.1 | 7.06 | 11 | A2 | 17.40 | 0.35 |
| Example 64 | 1.0 | 50 | 1.49 | 0.95 | 101.8 | 6.44 | 97 | A2 | 17.41 | 0.36 |
| Example 65 | 1.6 | 5 | 1.49 | 0.95 | 102.8 | 7.26 | 98 | A2 | 17.54 | 0.49 |
| Example 66 | 1.6 | 10 | 1.49 | 0.95 | 101.5 | 7.08 | 99 | A2 | 17.52 | 0.47 |
| Example 67 | 1.6 | 20 | 1.49 | 0.95 | 98.91 | 5.92 | 100 | A2 | 17.38 | 0.33 |
| Example 68 | 1.6 | 30 | 1.49 | 0.95 | 96.05 | 5.88 | 101 | A2 | 17.25 | 0.20 |
| Example 69 | 1.6 | 50 | 1.49 | 0.95 | 94.47 | 5.80 | 102 | A2 | 17.21 | 0.16 |
| Example 70 | 0.6 | 10 | 1.49 | 1.01 | 93.85 | 27.75 | 103 | A2 | 17.19 | 0.14 |
| Example 71 | 0.6 | 20 | 1.49 | 1.01 | 94.09 | 24.66 | 104 | A2 | 17.20 | 0.15 |
| Example 72 | 0.6 | 30 | 1.49 | 1.01 | 94.49 | 21.44 | 105 | A2 | 17.21 | 0.16 |
| Example 73 | 0.6 | 50 | 1.49 | 1.01 | 94.99 | 17.12 | 106 | A2 | 17.23 | 0.18 |
| Example 74 | 1.0 | 5 | 1.49 | 1.01 | 94.54 | 16.25 | 107 | A2 | 17.22 | 0.17 |
| Example 75 | 1.0 | 10 | 1.49 | 1.01 | 95.74 | 15.04 | 108 | A2 | 17.24 | 0.19 |
| Example 76 | 1.0 | 20 | 1.49 | 1.01 | 95.96 | 14.48 | 109 | A2 | 17.25 | 0.20 |
| Example 4 | 1.0 | 30 | 1.49 | 1.01 | 96.60 | 11.73 | 17 | A2 | 17.27 | 0.22 |
| Example 77 | 1.0 | 50 | 1.49 | 1.01 | 97.25 | 9.03 | 110 | A2 | 17.30 | 0.25 |
| Example 78 | 1.6 | 5 | 1.49 | 1.01 | 103.1 | 3.26 | 111 | A2 | 17.54 | 0.49 |
| Example 79 | 1.6 | 10 | 1.49 | 1.01 | 101.2 | 2.79 | 112 | A2 | 17.49 | 0.44 |
| Example 80 | 1.6 | 20 | 1.49 | 1.01 | 99.65 | 2.62 | 113 | A2 | 17.45 | 0.40 |
| Example 81 | 1.6 | 30 | 1.49 | 1.01 | 98.57 | 2.46 | 114 | A2 | 17.43 | 0.38 |
| Example 82 | 1.6 | 50 | 1.49 | 1.01 | 97.93 | 2.12 | 115 | A2 | 17.35 | 0.30 |
| Example 83 | 0.6 | 10 | 1.49 | 1.05 | 94.19 | 17.31 | 116 | A2 | 17.19 | 0.14 |
| Example 84 | 0.6 | 20 | 1.49 | 1.05 | 95.02 | 12.44 | 117 | A2 | 17.23 | 0.18 |
| Example 85 | 0.6 | 30 | 1.49 | 1.05 | 95.87 | 8.89 | 118 | A2 | 17.24 | 0.19 |
| Example 86 | 0.6 | 50 | 1.49 | 1.05 | 96.43 | 9.75 | 119 | A2 | 17.26 | 0.21 |
| Example 87 | 1.0 | 5 | 1.49 | 1.05 | 93.92 | 15.53 | 120 | A2 | 17.19 | 0.14 |
| Example 88 | 1.0 | 10 | 1.49 | 1.05 | 94.33 | 11.07 | 121 | A2 | 17.20 | 0.15 |
| Example 89 | 1.0 | 20 | 1.49 | 1.05 | 94.62 | 8.52 | 122 | A2 | 17.20 | 0.15 |
| Example 5 | 1.0 | 30 | 1.49 | 1.05 | 95.81 | 7.29 | 19 | A2 | 17.23 | 0.18 |
| Example 90 | 1.0 | 50 | 1.49 | 1.05 | 96.75 | 6.06 | 123 | A2 | 17.28 | 0.23 |
| Example 91 | 1.6 | 5 | 1.49 | 1.05 | 103.5 | 7.36 | 124 | A2 | 17.58 | 0.53 |
| Example 92 | 1.6 | 10 | 1.49 | 1.05 | 100.5 | 7.24 | 125 | A2 | 17.51 | 0.46 |
| Example 93 | 1.6 | 20 | 1.49 | 1.05 | 100.0 | 7.19 | 126 | A2 | 17.49 | 0.44 |
| Example 94 | 1.6 | 30 | 1.49 | 1.05 | 99.79 | 6.05 | 127 | A2 | 17.46 | 0.41 |
| Example 95 | 1.6 | 50 | 1.49 | 1.05 | 98.59 | 5.46 | 128 | A2 | 17.37 | 0.32 |

Table 5 shows the properties of the transmittance enhancement film prepared when the B/R value and the coating thickness are changed under the conditions of different α and n_{B}, and the power generation efficiency η and the gain in power generation efficiency (Δη) of the module when the transmittance enhancement film is assembled on the solar cell module (Module A2). The B/R value and the α value are as defined above, and the gain in module power generation efficiency (Δη) is the difference between the power generation efficiency of the solar cell module A2 and the power generation efficiency of the solar cell module A.

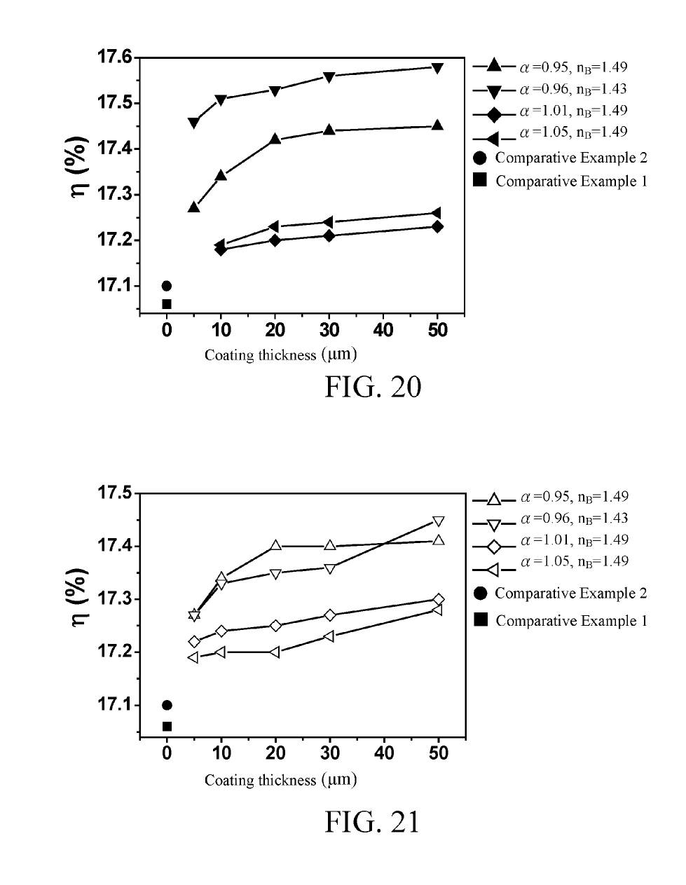

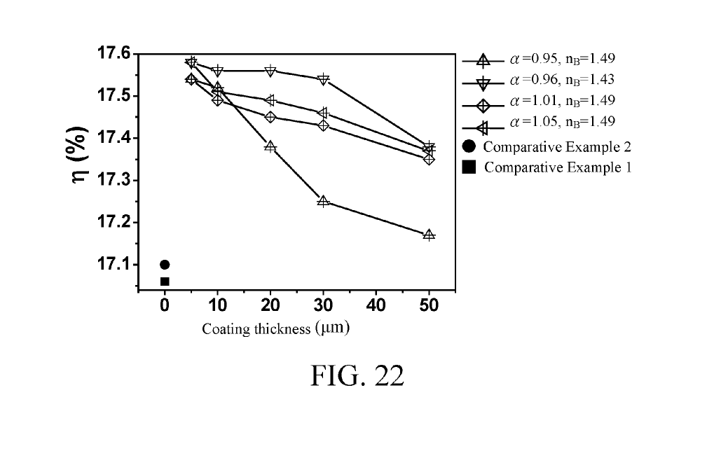

In Table 5, Film Examples and the results of the performance of the corresponding solar cell assemblies are as shown in FIGS. 20 to 22. FIG. 20 illustrates the influence of α, n_{B}, and the coating thickness of the transmittance enhancement film on the power generation efficiency η while B/R=0.6 is fixed. FIG. 21 illustrates the influence of α, n_{B}, and the coating thickness of the transmittance enhancement film on the power generation efficiency η while B/R=1.0 is fixed. FIG. 22 illustrates the influence of α, n_{B}, and the coating thickness of the transmittance enhancement film on the power generation efficiency η while B/R=1.6 is fixed.

It can be seen from Table 5 and FIGS. 20 and 21 that, as for the transmittance enhancement films (α=0.95, n_{B}=1.49: Examples 56-60; α=0.96, n_{B}=1.43: Examples 42-46; α=1.01, n_{B}=1.49: Examples 70-73; α=1.05, n_{B}=1.49: Examples 83-86) with the B/R value being fixed at 0.6 and the transmittance enhancement film (α=0.95, n_{B}=1.49: Examples 1 and 61-64; α=0.96, n_{B}=1.43: Examples 2 and 47-50; α=1.01, n_{B}=1.49 Examples 4 and 74-77; α=1.05, n_{B}=1.49: Examples 5 and 87-90) with the B/R value being fixed at 1.0, the total light transmittance Tt and the power generation efficiency η obtained after the transmittance enhancement film is assembled into a solar cell module increase with the increase of the coating thickness of the film, and the efficiency is higher than the conventional solar cell module (Module Example 1; solar cell module A).

It can be seen from Table 5 and FIG. 22 that, as for the transmittance enhancement film (α=0.95, n_{B}=1.49: Examples 65-69; α=0.96, n_{B}=1.43: Examples 51-55; α=1.01, n_{B}=1.49: Examples 78-82; α=1.05, n_{B}=1.49: Examples 91-95) with the B/R value being fixed at 1.6, the total light transmittance Tt and the power generation efficiency η obtained after the transmittance enhancement film is assembled into a solar cell module decrease with the increase of the coating thickness of the film, but the efficiency is still higher than the conventional solar cell module (Module Example 1; solar cell module A).

The analysis results above prove that when the solar cell module has a transmittance enhancement film meeting the conditions 0.95<α<1.05 and n_{B}<1.5, and the transmittance enhancement film has a B/R<1.5, the thicker the coating layer of the transmittance enhancement film is (for example, 50 μm), the higher the module power generation efficiency will be; and when the transmittance enhancement film has a B/R≧1.5, the thinner the coating layer of the transmittance enhancement film (for example, 5 μm), the higher the module power generation efficiency will be.

We claim:

1. A transmittance enhancement film comprising a substrate and a coating layer on the substrate wherein the coating layer comprises a plurality of organic particles and a binder, the organic particles have a refractive index of less than 1.5 and the refractive index ratio of the organic particles to the binder is in the range from 0.95 to 1.05.

2. The transmittance enhancement film according to claim 1, wherein the organic particles have a mean particle size in the range from 0.5 μm to 30 μm.

3. The transmittance enhancement film according to claim 1, wherein the organic particles are present in the amount of about 40 to about 200 parts by weight based on 100 parts by weight of the solids content of the binder.

4. The transmittance enhancement film according to claim 1, wherein the coating layer is applied onto the light incident surface or light emitting surface of the substrate.

5. The transmittance enhancement film according to claim 1, wherein the substrate is a glass or plastic substrate.

6. The transmittance enhancement film according to claim 1, wherein the organic particles are selected from the group consisting of poly(meth)acrylate resin, polyurethane resin, silicone resin and a mixture thereof.

7. The transmittance enhancement film according to claim 1, wherein the binder is selected from the group consisting of (meth)acrylic resin, silicone resin, polyamide resin, epoxy resin, fluorocarbon resin, polyimide resin, polyurethane resin, alkyd resin, polyester resin and a mixture thereof.

8. The transmittance enhancement film according to claim 7, wherein the binder is fluorocarbon resin.

9. The transmittance enhancement film according to claim 8, wherein the fluorocarbon resin includes a copolymer of a fluoroolefin monomer and an alkyl vinyl ether monomer.

10. A solar cell module comprising the transmittance enhancement film according to any one of claims 1 to 9.
